(19) United States
(12) Patent Application Publication
(10) Pub. No.: US 2025/0204222 A1
(43) Pub. Date: Jun. 19, 2025

(54) DISPLAY PANEL AND DISPLAY APPARATUS

(71) Applicant: Tianma Advanced Display Technology Institute (Xiamen) Co., Ltd., Xiamen (CN)

(72) Inventors: Yingying WU, Xiamen (CN); Peixuan CHEN, Xiamen (CN); Wenxin JIANG, Xiamen (CN)

(21) Appl. No.: 19/066,197

(22) Filed: Feb. 28, 2025

(30) Foreign Application Priority Data
Nov. 29, 2024 (CN) 202411730545.8

(51) Int. Cl. H10K 59/80; H10K 59/124

(52) U.S. Cl. CPC H10K 59/873; H10K 59/124

(57) ABSTRACT

A display panel and a display apparatus are provided. The display panel includes: a device region; a peripheral region located on a side of the device region facing towards an edge of the display panel; a substrate; a transistor array layer; an organic planarization layer; and an encapsulation layer. The organic planarization layer is located on a side of the transistor array layer facing away from the substrate, and the encapsulation layer is located on a side of the organic planarization layer facing away from the substrate. The organic planarization layer and the encapsulation layer extend from the device region to the peripheral region. In the peripheral region, the organic planarization layer is provided with a groove, and the encapsulation layer fills at least part of the groove.

### CROSS-REFERENCE TO RELATED APPLICATIONS

The present application claims priority to Chinese Application No. 202411730545.8 with the application title of “DISPLAY PANEL AND DISPLAY APPARATUS”, filed on Nov. 29, 2024, the content of which is incorporated herein by reference in its entirety.

### TECHNICAL FIELD

The present disclosure relates to the field of display technologies, and particularly, to a display panel and a display apparatus.

### BACKGROUND

Micro Light Emitting Diode (Micro-LED) display panels have advantages such as high brightness, long lifespan, fast response and high resolution, and have become a focus of current research.

In the related Micro-LED display panels, external water vapor can easily invade the interior of the display panel along the organic film, and erode the components inside the display panel, causing device failure. Therefore, a solution is urgently needed.

### SUMMARY

An aspect of the present disclosure provides a display panel. The display panel includes: a device region; a peripheral region located on a side of the device region facing towards an edge of the display panel; a substrate; a transistor array layer; an organic planarization layer; and an encapsulation layer. The organic planarization layer is located on a side of the transistor array layer facing away from the substrate, and the encapsulation layer is located on a side of the organic planarization layer facing away from the substrate. The organic planarization layer and the encapsulation layer extend from the device region to the peripheral region. In the peripheral region, the organic planarization layer is provided with a groove, and the encapsulation layer fills at least part of the groove.

Another aspect of the present disclosure provides a display apparatus. The display apparatus includes a display panel. The display panel includes: a device region; a peripheral region located on a side of the device region facing towards an edge of the display panel; a substrate; a transistor array layer; an organic planarization layer; and an encapsulation layer. The organic planarization layer is located on a side of the transistor array layer facing away from the substrate, and the encapsulation layer is located on a side of the organic planarization layer facing away from the substrate. The organic planarization layer and the encapsulation layer extend from the device region to the peripheral region. In the peripheral region, the organic planarization layer is provided with a groove, and the encapsulation layer fills at least part of the groove.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may further be obtained based on these drawings.

FIG. 1 is a structural schematic diagram of a display panel in the related art;

FIG. 2 is a planar schematic diagram of a display panel according to some embodiments of the present disclosure;

FIG. 3 is a cross-sectional view along a line NN′ in FIG. 2 according to some embodiments of the present disclosure;

FIG. 4 is a cross-sectional view along a line NN′ in FIG. 2 according to some embodiments of the present disclosure;

FIG. 5 is a partially enlarged schematic diagram of a first peripheral region according to some embodiments of the present disclosure;

FIG. 6 is a cross-sectional view along a line MM′ in FIG. 5 according to some embodiments of the present disclosure;

FIG. 7 is a cross-sectional view along a line MM′ in FIG. 5 according to some embodiments of the present disclosure;

FIG. 8 is a cross-sectional view along a line CC′ in FIG. 5 according to some embodiments of the present disclosure;

FIG. 9 is a partially enlarged schematic diagram of a first peripheral region according to some embodiments of the present disclosure;

FIG. 10 is a partially enlarged schematic diagram of a first peripheral region according to some embodiments of the present disclosure;

FIG. 11 is a cross-sectional view along a line CC′ in FIG. 5 according to some embodiments of the present disclosure;

FIG. 12 is a partially enlarged schematic diagram of a first peripheral region according to some embodiments of the present disclosure;

FIG. 13 is a cross-sectional view along a line MM′ in FIG. 5 according to some embodiments of the present disclosure;

FIG. 14 is a cross-sectional view along a line MM′ in FIG. 5 according to some embodiments of the present disclosure;

FIG. 15 is a partially enlarged schematic diagram of a first peripheral region according to some embodiments of the present disclosure;

FIG. 16 is a cross-sectional view along a line DD′ in FIG. 15 according to some embodiments of the present disclosure;

FIG. 17 is a cross-sectional view along a line EE′ in FIG. 15 according to some embodiments of the present disclosure;

FIG. 18 is a partially enlarged schematic diagram of a first peripheral region according to some embodiments of the present disclosure;

FIG. 19 is a partially enlarged schematic diagram of a first peripheral region according to some embodiments of the present disclosure;

FIG. 20 is a partially enlarged schematic diagram of a first peripheral region according to some embodiments of the present disclosure;

FIG. 21 is a partially enlarged schematic diagram of a first peripheral region according to some embodiments of the present disclosure;

FIG. 22 is a cross-sectional view along a line FF′ in FIG. 21 according to some embodiments of the present disclosure;

FIG. 23 is a partially enlarged schematic diagram of a first peripheral region according to some embodiments of the present disclosure;

FIG. 24 is a planar schematic diagram of a display panel according to some embodiments of the present disclosure; and

FIG. 25 is a schematic diagram of a display apparatus according to some embodiments of the present disclosure.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

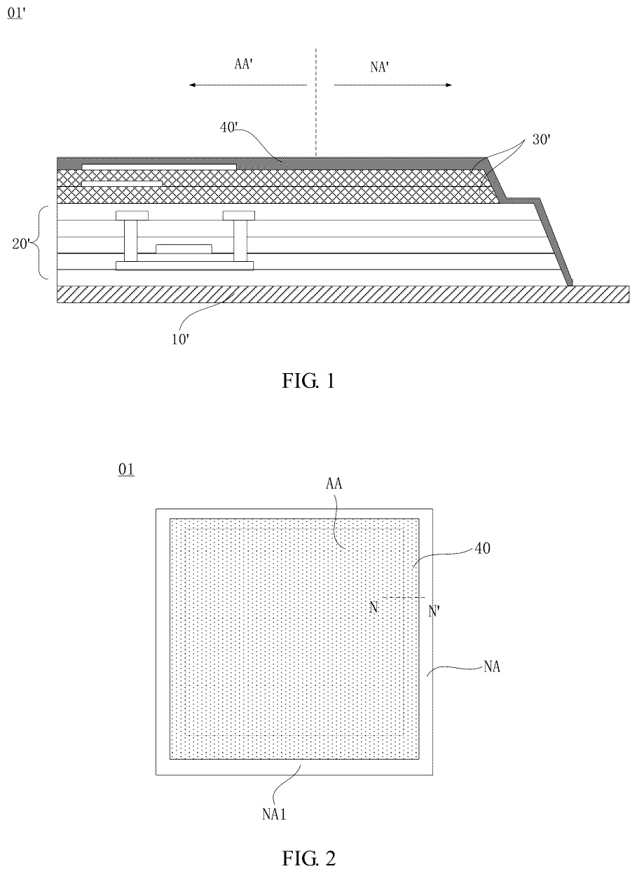

FIG. 1 is a structural schematic diagram of a display panel in the related art.

In the related art, as shown in FIG. 1, the display panel 01′ has a device region AA′ and a peripheral region NA′ located on a side of the device region AA′ facing towards an edge of the display panel 01′. The peripheral region NA′ surrounds the device region AA′.

As shown in FIG. 1, the display panel 01′ includes a substrate 10′, a transistor array layer 20′ located on a side of the substrate 10′, an organic planarization layer 30′ and a first inorganic layer 40′. The organic planarization layer 30′ is located on a side of the transistor array layer 20′ facing away from the substrate 10′, and the first inorganic layer 40′ is located on a side of the organic planarization layer 30′ facing away from the substrate 10′. Both the organic planarization layer 30′ and the first inorganic layer 40′ extend from the device region AA′ to the peripheral region NA′.

In the peripheral region NA′, the first inorganic layer 40′ covers the sidewall of the organic planarization layer 30′ to prevent external water vapor from intruding the device region AA′ of the display panel 01′ through the organic planarization layer 30′.

However, in the display panel 01′ of the related art, the thickness of the organic planarization layer 30′ is usually relatively large. In the peripheral region NA′, there is a relatively large step at the sidewall of the organic planarization layer 30′. This results in a poor effect of the first inorganic layer 40′ for covering the sidewall of the organic planarization layer 30′. The first inorganic layer 40′ at the sidewall position of the organic planarization layer 30′ is relatively thin, during subsequent manufacturing processes, the first inorganic layer 40′ at the sidewall position of the organic planarization layer 30′ may be damaged. Once damaged, external water vapor will invade the interior of the display panel 01′ along the organic planarization layer 30′, causing device failure in the display panel 01′.

In view of this, the present disclosure provides a technical solution to solve the problems in the related art.

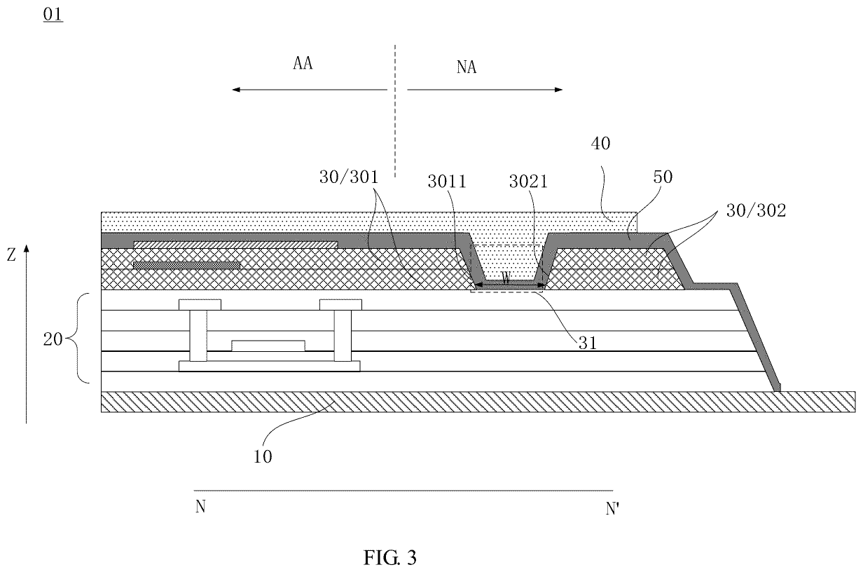

FIG. 2 is a planar schematic diagram of a display panel according to some embodiments of the present disclosure, and FIG. 3 is a cross-sectional view along a line NN′ in FIG. 2.

Embodiments of the present disclosure provide a display panel 01. As shown in FIG. 2, the display panel 01 has a device region AA and a peripheral region NA located on a side of the device region AA facing towards an edge of the display panel 01. The peripheral region NA may surround the device region AA. In some embodiments of the present disclosure, the device region AA may include electronic components such as light-emitting devices, pixel circuits, shift registers, electrostatic discharge units, and demultiplexers in the display panel 01.

As shown in combination with FIG. 3, the display panel 01 includes a substrate 10, a transistor array layer 20 located on a side of the substrate 10, an organic planarization layer 30, and an encapsulation layer 40. The organic planarization layer 30 is located on a side of the transistor array layer 20 facing away from the substrate 10, and the encapsulation layer 40 is located on a side of the organic planarization layer 30 facing away from the substrate 10. The organic planarization layer 30 may be a single-layer or multi-layer structure.

In some embodiments of the present disclosure, both the organic planarization layer 30 and the encapsulation layer 40 extend from the device region AA to the peripheral region NA. In the peripheral region NA, the organic planarization layer 30 is provided with a groove 31, and the encapsulation layer 40 fills at least part of the groove 31. The encapsulation layer 40 is made of a different material from the organic planarization layer 30.

It can be understood that in the display panel 01, the encapsulation layer 40 is usually a continuous structure.

In some embodiments of the present disclosure, by providing a groove 31 in the organic planarization layer 30, the solid portion of the organic planarization layer 30 may be disconnected or terminated at the groove 31. As shown in FIG. 3, if the solid portion of the organic planarization layer 30 is disconnected at the groove 31 and the encapsulation layer 40 fills at least part of the groove 31, the encapsulation layer 40 may be located between the disconnected solid portions of the organic planarization layer 30, so that the path through which the organic planarization layer 30 transmits external water vapor is blocked, thereby preventing external water vapor from intruding the interior of the display panel 01 through the organic planarization layer 30, and not damaging the components inside the display panel 01.

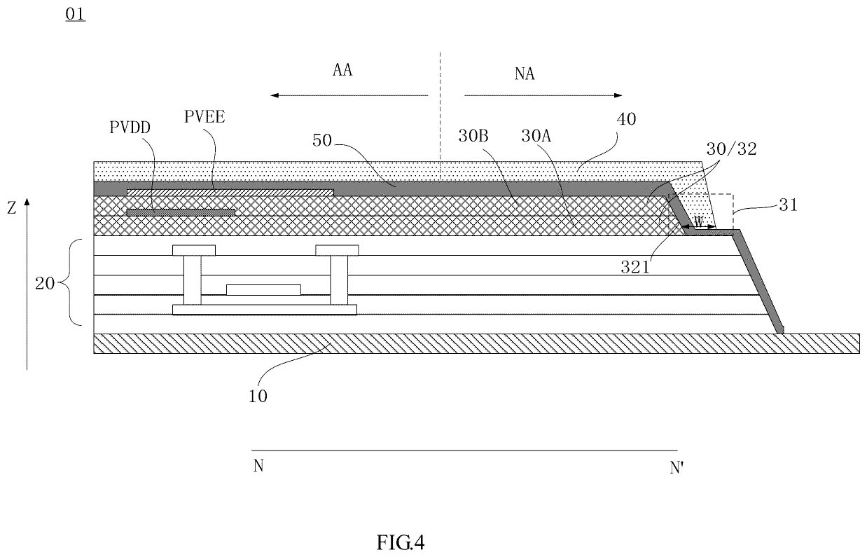

As shown in FIG. 4, which is a cross-sectional view along the line NN′ in FIG. 2, if the solid portion of the organic planarization layer 30 terminates at the groove 31, and the encapsulation layer 40 fills at least part of the groove 31, the encapsulation layer 40 may relatively reliably cover the sidewall of the solid portion of the organic planarization layer 30 facing towards the edge of the display panel 01, so that external water and oxygen are prevented from entering the organic planarization layer 30, thereby preventing external water vapor from intruding the interior of the display panel 01 along the organic planarization layer 30, and not damaging the components inside the display panel 01.

In some embodiments of the present disclosure, the encapsulation layer 40 is a water-blocking layer, that is, the encapsulation layer 40 has water-blocking properties. In this way, after the encapsulation layer 40 fills the groove 31, it can prevent external water vapor intruding the interior of the display panel 01 along the organic planarization layer 30.

Furthermore, the encapsulation layer 40 is an organic water-blocking layer, so that the encapsulation layer 40 not only has high water-blocking properties but also can be easily made relatively thick, thereby improving the water-blocking and encapsulation effects of the encapsulation layer 40.

In some embodiments of the present disclosure, the encapsulation layer 40 may be provided on the side of the organic planarization layer 30 facing away from the substrate 10 by printing. In some embodiments of the present disclosure, it may also be prepared by other methods, and the present disclosure does not have any limitations in this regard.

In some embodiments of the present disclosure, as shown in FIG. 3 and FIG. 4, the display panel 01 further includes a first inorganic layer 50. The first inorganic layer 50 extends from the device region AA to the peripheral region NA, and the first inorganic layer 50 is located between the encapsulation layer 40 and the organic planarization layer 30.

In the peripheral region NA, the first inorganic layer 50 adheres to a surface of the organic planarization layer 30. In some embodiments of the present disclosure, as shown in FIG. 3 and FIG. 4, in the peripheral region NA, the first inorganic layer 50 conformably adheres to the surface of the organic planarization layer 30. Based on this arrangement, the first inorganic layer 50 can cover the sidewall of the organic planarization layer 30.

Since inorganic layers usually have water-blocking properties, using the first inorganic layer 50 to cover the sidewall of the organic planarization layer 30 is beneficial for further improving the ability to prevent external water and oxygen from intruding the interior of the display panel 01 along the organic planarization layer 30.

In some embodiments of the present disclosure, as shown in FIG. 3, in the peripheral region NA, the organic planarization layer 30 includes a first sub-portion 301 and a second sub-portion 302, and the groove 31 is located between the first sub-portion 301 and the second sub-portion 302. That is, the first sub-portion 301 and the second sub-portion 302 are disconnected at the groove 31.

In some embodiments of the present disclosure, by providing the groove 31 between the first sub-portion 301 and the second sub-portion 302, when the encapsulation layer 40 fills at least part of the groove 31, the encapsulation layer 40 can be located between the disconnected first sub-portion 301 and the second sub-portion 302, so that the path through which the organic planarization layer 30 transmits external water vapor is blocked, thereby preventing external water vapor from intruding the interior of the display panel 01 through the organic planarization layer 30, and not damaging the components inside the display panel 01.

Moreover, providing the groove 31 between the first sub-portion 301 and the second sub-portion 302 is beneficial for enabling the encapsulation layer 40 to completely cover the groove 31 in a direction Z perpendicular to the plane of the display panel 01, which is conducive to completely filling the groove 31 with the encapsulation layer 40 and improving the ability to block the water vapor transmission path along the organic planarization layer 30.

In some embodiments of the present disclosure, as shown in FIG. 3, the second sub-portion 302 is located on a side of the first sub-portion 301 facing towards the edge of the display panel 01. The first sub-portion 301 includes a first side surface 3011 facing towards the second sub-portion 302, and the second sub-portion 302 includes a second side surface 3021 facing towards the first sub-portion 301. The groove 31 is located between the first side surface 3011 and the second side surface 3021. In the direction Z perpendicular to the plane of the display panel 01, the encapsulation layer 40 covers the first side surface 3011 and the second side surface 3021. That is, the encapsulation layer 40 fills at least part of the groove 31 and covers the first side surface 3011 and the second side surface 3021. This is beneficial for improving the ability of the encapsulation layer 40 to block the water vapor transmission along the organic planarization layer 30, thereby further preventing external water and oxygen intruding the interior of the display panel 01 along the organic planarization layer 30.

Furthermore, as shown in FIG. 3, in the direction Z perpendicular to the plane of the display panel 01, the encapsulation layer 40 protrudes from the groove 31. That is, the encapsulation layer 40 can completely fill the groove 31. Based on this arrangement, on the one hand, there can be more encapsulation material between the first sub-portion 301 and the second sub-portion 302, improving the ability of the encapsulation layer 40 to block the water vapor transmission of the organic planarization layer 30. On the other hand, the encapsulation layer 40 can also play a planarizing role, thereby achieving the preparation continuity of the subsequent layers and avoiding the disconnection of the subsequent layers at the groove 31.

As shown in FIG. 4, in some embodiments of the present disclosure, the organic planarization layer 30 includes a solid portion 32, and the groove 31 is located on a side of the solid portion 32 facing towards the edge of the display panel 01. The solid portion 32 includes a third side surface 321 on a side facing towards the edge of the display panel 01. That is, the solid portion 32 of the organic planarization layer 30 terminates at the groove 31, and the groove 31 is located between the third side surface 321 of the solid portion 32 and the edge of the display panel 01.

In some embodiments of the present disclosure, in the direction Z perpendicular to the plane of the display panel 01, the encapsulation layer 40 covers the third side surface 321.

In some embodiments of the present disclosure, by providing the groove 31 between the third side surface 321 of the solid portion 32 and the edge of the display panel 01, and the encapsulation layer 40 covering the third side surface 321 in the direction Z perpendicular to the plane of the display panel 01, when the encapsulation layer 40 fills at least part of the groove 31, the encapsulation layer 40 can better cover the third side surface 321 of the solid portion 32, thereby preventing external water vapor intruding the organic planarization layer 30, and further preventing external water vapor from intruding the interior of the display panel 01 along the organic planarization layer 30.

In addition, providing the groove 31 adjacent to the edge of the display panel 01 is also beneficial for reducing the preparation difficulty of the groove 31 in the process and facilitating the encapsulation layer 40 to cover the third side surface 321.

In some embodiments of the present disclosure, as shown in FIG. 3 and FIG. 4, in the direction Z perpendicular to the plane of the display panel 01, the encapsulation layer 40 overlaps the groove 31, and an overlapping width of the encapsulation layer 40 and the groove 31 is W, with W≥10 μm. Here, the sign “W” refer to the overlapping width of the bottom surface of the encapsulation layer 40 adjacent to the substrate 10 and the groove 31.

Based on this arrangement, the encapsulation layer 40 at the third side surface 321 of the solid portion 32 can be made relatively thick, thereby achieving that the encapsulation layer 40 can relatively reliably cover the third side surface 321 of the solid portion 32, thereby preventing external water vapor from intruding the organic planarization layer 30 through the encapsulation layer 40 and then along the organic planarization layer 30 into the interior of the display panel 01.

In addition, for the structure where the groove 31 is located between the first sub-portion 301 and the second sub-portion 302, if the overlapping width of the encapsulation layer 40 and the groove 31 is not less than 10 μm, it can ensure that the space separating the first sub-portion 301 and the second sub-portion 302 by the groove 31 is relatively large, and the encapsulation layer 40 between the first sub-portion 301 and the second sub-portion 302 can be made relatively thick. This is beneficial for ensuring the ability of the encapsulation layer 40 to block the water vapor intrusion into the interior of the display panel 01 along the organic planarization layer 30, thereby improving the reliability of the encapsulation layer 40 in preventing external water vapor intruding the interior of the display panel 01 along the organic planarization layer 30.

In some embodiments of the present disclosure, as shown in FIG. 4, the display panel 01 further includes a first power supply line PVDD and a second power supply line PVEE. The first power supply line PVDD and the second power supply line PVEE may be located in different layers.

In some embodiments of the present disclosure, the organic planarization layer 30 includes a first sub-layer 30A and a second sub-layer 30B. The first sub-layer 30A is located on a side of the second sub-layer 30B adjacent to the substrate 10. The first power supply line PVDD is located between the first sub-layer 30A and the second sub-layer 30B, and the second power supply line PVEE is located on a side of the second sub-layer 30B facing away from the first sub-layer 30A.

In some embodiments of the present disclosure, the first power supply line PVDD is disposed on a surface of the first sub-layer 30A, and the second power supply line PVEE is disposed on a surface of the second sub-layer 30B.

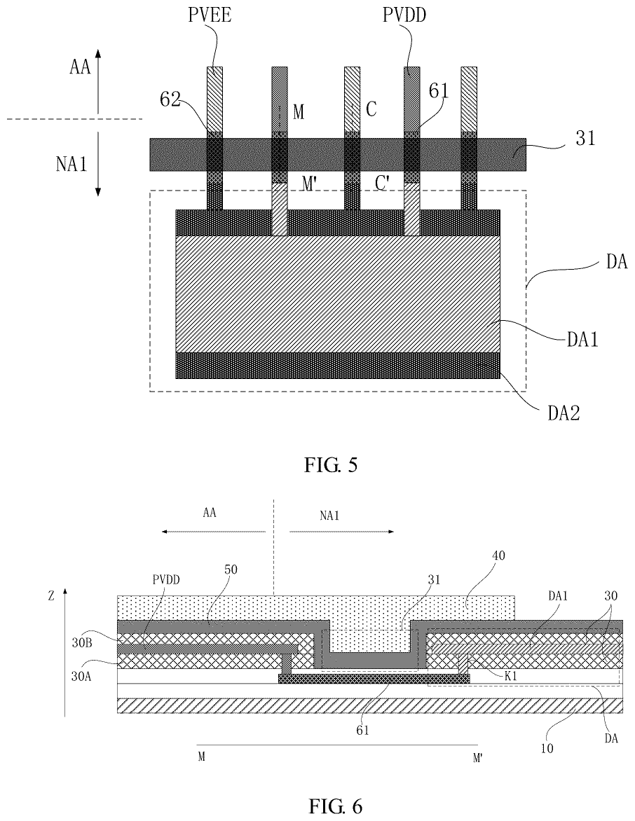

FIG. 5 is a partially enlarged schematic diagram of a first peripheral region according to some embodiments of the present disclosure, and FIG. 6 is a cross-sectional view along a line MM′ in FIG. 5.

In some embodiments of the present disclosure, as shown in FIG. 2, the peripheral region NA includes a first peripheral region NA1 located on a side of the device region AA. The first peripheral region NA1 is electrically connected to a circuit board (not shown in the drawings), and the circuit board may be used to transmit display signals. The first peripheral region NA1 may be the “lower” border of the display panel 01.

As shown in combination with FIG. 5 and FIG. 6, the first peripheral region NA1 includes a power supply line transfer region DA. The power supply line transfer region DA may be used to receive the power signals transmitted by the circuit board and transmit the power signals to the first power supply line PVDD and the second power supply line PVEE. In some embodiments of the present disclosure, the groove 31 is located between the power supply line transfer region DA and the device region AA.

In some embodiments of the present disclosure, as shown in FIG. 6, in the direction Z perpendicular to the plane of the display panel 01, the encapsulation layer 40 covers the groove 31, and the encapsulation layer 40 may completely fill the groove 31.

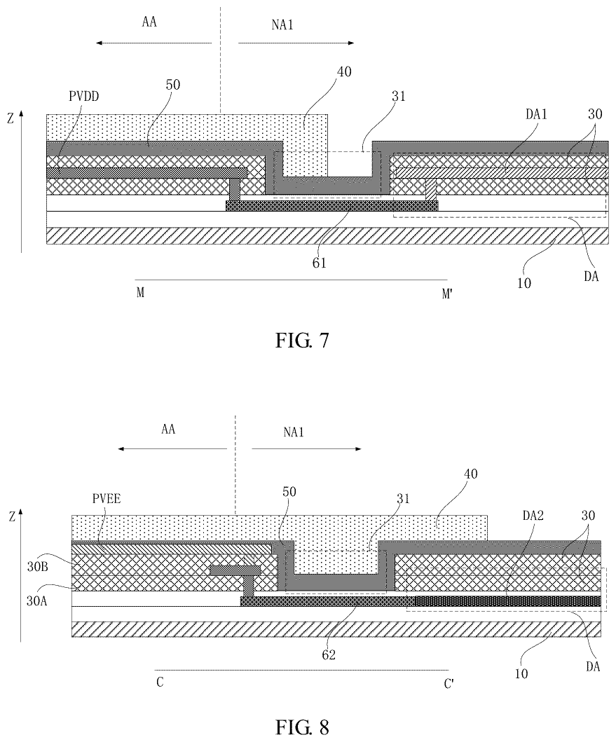

In some embodiments of the present disclosure, as shown in FIG. 7, which is a cross-sectional view along the line MM′ in FIG. 5, in the direction Z perpendicular to the plane of the display panel 01, the encapsulation layer 40 partially overlaps the groove 31, and the encapsulation layer 40 may cover the sidewall of the solid portion of the organic planarization layer 30 adjacent to the device region AA. In some embodiments of the present disclosure, a first inorganic layer 50 may be provided between the encapsulation layer 40 and the solid portion of the organic planarization layer 30.

In some embodiments of the present disclosure, by providing the groove 31 between the power supply line transfer region DA and the device region AA, on the one hand, the groove 31 can be closer to the device region AA, which is beneficial for filling the groove 31 with the encapsulation layer 40, so that the encapsulation layer 40 is used to block the path through which the organic planarization layer 30 transmits external water vapor. On the other hand, since there are usually no electrodes with a large area between the power supply line transfer region DA and the device region AA, it is beneficial to avoiding the mutual influence between the groove 31 and the electrodes with a large area in the first peripheral region NA1, reducing the design difficulty of the display panel 01.

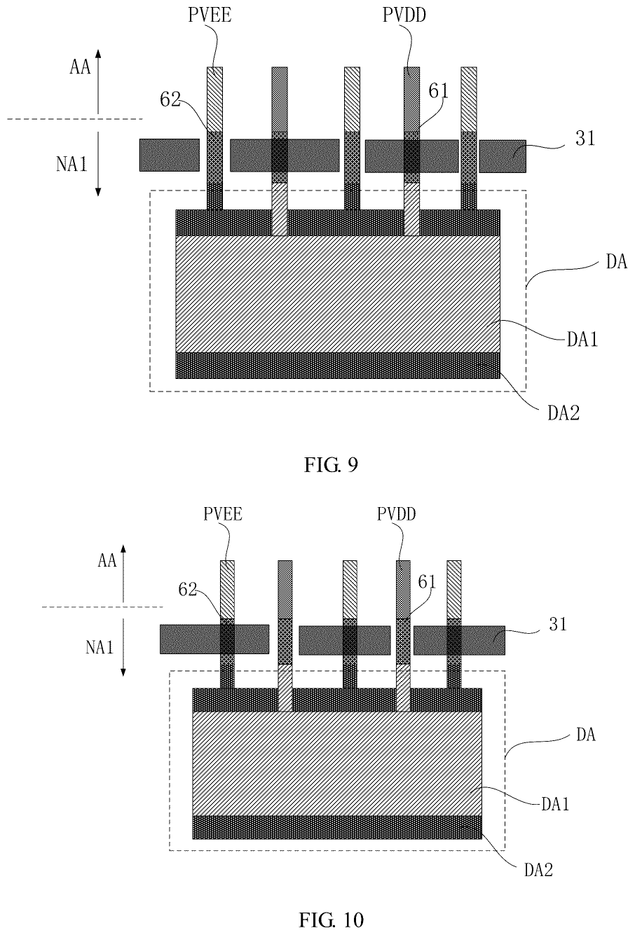

FIG. 8 is a cross-sectional view along a line CC′ in FIG. 5.

In some embodiments of the present disclosure, as shown in combination with FIG. 6 and FIG. 8, the first peripheral region NA1 includes a first transfer line 61 and a second transfer line 62. The first transfer line 61 is electrically connected to the first power supply line PVDD, and the second transfer line 62 is electrically connected to the second power supply line PVEE. Both the first transfer line 61 and the second transfer line 62 extend to the power supply line transfer region DA. That is, the first power supply line PVDD may extend to the power supply line transfer region DA through the first transfer line 61, and the second power supply line PVEE may extend to the power supply line transfer region DA through the second transfer line 62.

In some embodiments of the present disclosure, in the direction Z perpendicular to the plane of the display panel 01, at least one of the first transfer line 61 and the second transfer line 62 overlaps the groove 31.

In some embodiments of the present disclosure, as shown in combination with FIG. 5, FIG. 6 and FIG. 8, in the direction Z perpendicular to the plane of the display panel 01, both the first transfer line 61 and the second transfer line 62 overlap the groove 31. Based on this arrangement, it is beneficial to make the groove 31 a continuous structure, which is conducive to realizing the all-round blocking of the path through which the organic planarization layer 30 transmits water vapor to the interior of the display panel 01.

In some embodiments of the present disclosure, as shown in combination with FIG. 6 and FIG. 8, both the first transfer line 61 and the second transfer line 62 are located on a side of the first sub-layer 30A adjacent to the substrate 10. From the previous analysis, there are usually transistors and connecting wiring on the side of the first sub-layer 30A adjacent to the substrate 10. By providing both the first transfer line 61 and the second transfer line 62 on the side of the first sub-layer 30A adjacent to the substrate 10, the first transfer line 61 and the second transfer line 62 can be manufactured on a same layer as other wiring on the side of the first sub-layer 30A adjacent to the substrate 10 without adding additional processes, thereby simplifying the manufacturing process of the display panel 01.

In some embodiments of the present disclosure, the first transfer line 61 and the second transfer line 62 are provided on a same layer, thereby simplifying the structural complexity of the display panel 01 and reducing the design difficulty of the display panel 01.

In some embodiments of the present disclosure, as shown in FIG. 9, which is a partially enlarged schematic diagram of a first peripheral region according to some embodiments of the present disclosure, in the direction perpendicular to the plane of the display panel 01, the first transfer line 61 overlaps the groove 31, and the second transfer line 62 does not overlap the groove 31. Based on this arrangement, the groove 31 can be a discontinuous structure that does not overlap the second transfer line 62. While ensuring that the path through which the organic planarization layer 30 transmits water vapor to the interior of the display panel 01 can be blocked to a large extent, the connection between the second transfer line 62 and the second power supply line PVEE does not require punching and layer changing, thereby simplifying the manufacturing process of the display panel 01 and reducing the manufacturing cost.

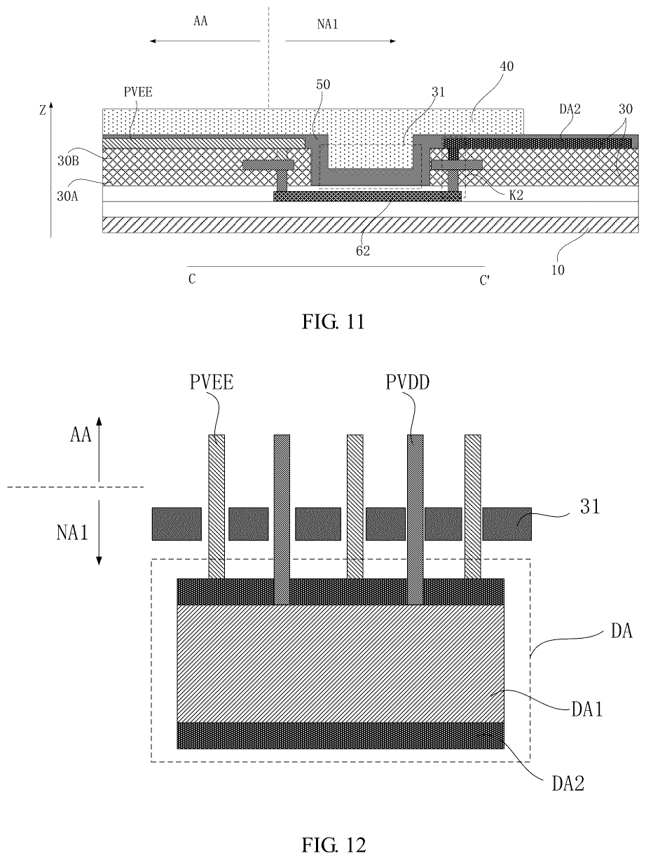

In some embodiments of the present disclosure, as shown in FIG. 10, which is a partially enlarged schematic diagram of the first peripheral region according to some embodiments of the present disclosure, in the direction perpendicular to the plane of the display panel 01, it may also be provided that the first transfer line 61 does not overlap the groove 31, and the second transfer line 62 overlaps the groove 31.

Combining with FIG. 5, FIG. 6 and FIG. 8, in some embodiments of the present disclosure, the power supply line transfer region DA includes a first transfer electrode DA1 and a second transfer electrode DA2. One end of the first transfer line 61 is electrically connected to the first power supply line PVDD, and the other end of the first transfer line 61 is electrically connected to the first transfer electrode DA1. One end of the second transfer line 62 is electrically connected to the second power supply line PVEE, and the other end of the second transfer line 62 is electrically connected to the second transfer electrode DA2. The first transfer electrode DA1 and the second transfer electrode DA2 may be located in different layers.

The first transfer electrode DA1 may receive the first power signals transmitted by the circuit board and transmit the first power signals to the first transfer line 61. The first transfer line 61 transmits the received first power signals to the first power supply line PVDD. The second transfer electrode DA2 may receive the second power signals transmitted by the circuit board and transmit the second power signals to the second transfer line 62. The second transfer line 62 transmits the received second power signals to the second power supply line PVEE.

In some embodiments of the present disclosure, the first transfer line 61 and the first transfer electrode DA1 are provided on a same layer, or the second transfer line 62 and the second transfer electrode DA2 are provided on a same layer. For example, as shown in combination with FIG. 6 and FIG. 8, the second transfer line 62 and the second transfer electrode DA2 are provided on a same layer, and the first transfer line 61 and the first transfer electrode DA1 are provided on different layers.

Based on this arrangement, there is no need to achieve electrical connection between the first transfer line 61 and the first transfer electrode DA1 through punching, or there is no need to achieve electrical connection between the second transfer line 62 and the second transfer electrode DA2 through punching, thereby simplifying the manufacturing process of the display panel 01 and saving costs.

In some embodiments of the present disclosure, as shown in FIG. 6, the first transfer line 61 is electrically connected to the first transfer electrode DA1 at least through a first via hole K1. As shown in FIG. 11, which is a cross-sectional view along the line CC′ in FIG. 5, the second transfer line 62 is electrically connected to the second transfer electrode DA2 at least through a second via hole K2. In this way, in the first peripheral region NA1, the first transfer electrode DA1 and the second transfer electrode DA2 may be provided in the layer with fewer wiring, thereby reducing the arrangement interference between the first transfer electrode DA1, the second transfer electrode DA2 and other wiring.

FIG. 12 is a partially enlarged schematic diagram of a first peripheral region according to some embodiments of the present disclosure.

In some embodiments of the present disclosure, both the first power supply line PVDD and the second power supply line PVEE extend to the power supply line transfer region DA. In the direction perpendicular to the plane of the display panel 01, at least one of the first power supply line PVDD and the second power supply line PVEE does not overlap the groove 31.

In some embodiments of the present disclosure, as shown in FIG. 12, in the direction perpendicular to the plane of the display panel 01, neither the first power supply line PVDD nor the second power supply line PVEE overlaps the groove 31.

In some embodiments of the present disclosure, the groove 31 may be a discontinuous structure. While ensuring that the path through which the organic planarization layer 30 transmits water vapor to the interior of the display panel 01 can be blocked to a large extent, it can avoid the first power supply line PVDD and/or the second power supply line PVEE extending to the power supply line transfer region DA through transfer lines on different layers, thereby simplifying the manufacturing process of the display panel 01 and reducing the manufacturing cost.

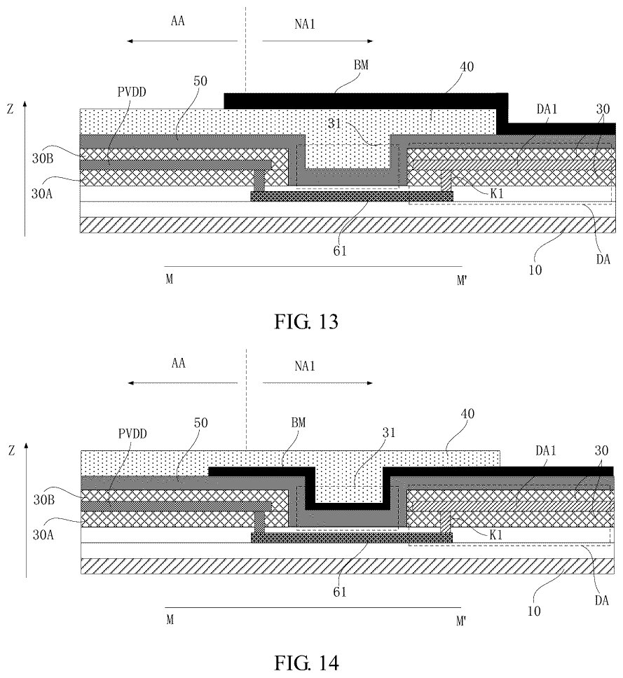

FIG. 13 is a cross-sectional view along the line MM′ in FIG. 5.

In some embodiments of the present disclosure, as shown in FIG. 13, the first peripheral region NA1 includes a light-shielding layer BM. The light-shielding layer BM is located on a side of the encapsulation layer 40 facing away from the substrate 10. Along the direction Z perpendicular to the plane of the display panel 01, the light-shielding layer BM overlaps the groove 31.

As analyzed previously, metal wiring, such as the first transfer line 61 electrically connected to the first power supply line PVDD, are provided on the side of the groove 31 facing towards the substrate 10. In some embodiments of the present disclosure, providing the light-shielding layer BM to overlap the groove 31 in the direction Z perpendicular to the plane of the display panel 01 is beneficial for the light-shielding layer BM to shield the metal wiring on the side of the groove 31 facing towards the substrate 10, thereby reducing the reflected light of these metal wiring and improving the display effect of the display panel 01.

FIG. 14 is a cross-sectional view along the line MM′ in FIG. 5.

In some embodiments of the present disclosure, as shown in FIG. 14, the first peripheral region NA1 includes a first inorganic layer 50 and a light-shielding layer BM. The first inorganic layer 50 adheres to a surface of the organic planarization layer 30. The first inorganic layer 50 may cover the sidewall of the solid portion of the organic planarization layer 30 facing towards the groove 31. The light-shielding layer BM is located between the encapsulation layer 40 and the first inorganic layer 50. Along the direction Z perpendicular to the plane of the display panel 01, the light-shielding layer BM overlaps the groove 31. The light-shielding layer BM may be filled in the groove 31.

Since inorganic layers usually have a water-blocking effect, in some embodiments of the present disclosure, the first inorganic layer 50 is provided to adhere to the surface of the organic planarization layer 30, and the first inorganic layer 50 may be used to isolate the organic planarization layer 30 and the light-shielding layer BM, avoiding the contact between the organic planarization layer 30 and the light-shielding layer BM, thereby preventing external water vapor from intruding the interior of the display panel 01 along the organic planarization layer 30 and the light-shielding layer BM.

In addition, as analyzed previously, metal wiring, such as the first transfer line 61 electrically connected to the first power supply line PVDD, are provided on the side of the groove 31 facing towards the substrate 10. In some embodiments of the present disclosure, providing the light-shielding layer BM to overlap the groove 31 in the direction Z perpendicular to the plane of the display panel 01 is beneficial for the light-shielding layer BM to shield the metal wiring on the side of the groove 31 facing towards the substrate 10, thereby reducing the reflected light of these metal wiring and improving the display effect of the display panel 01.

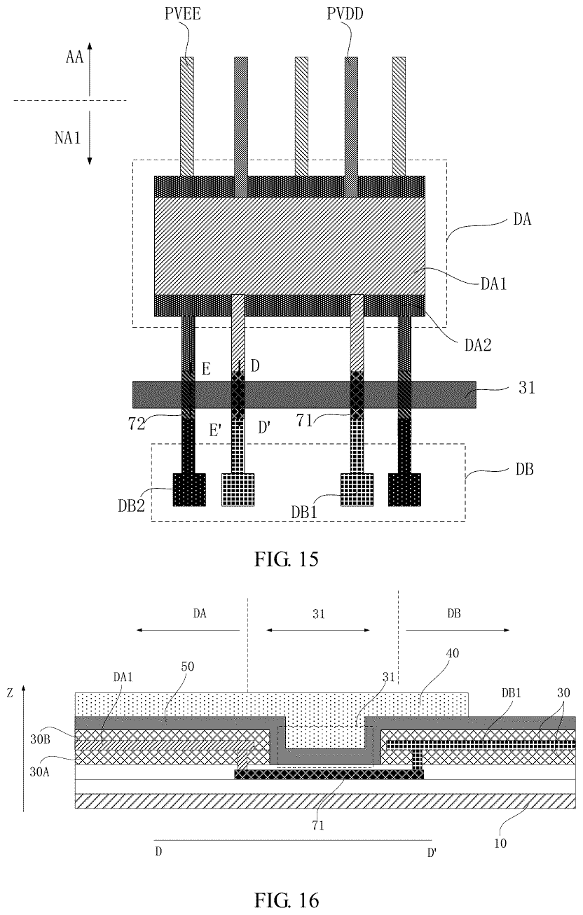

FIG. 15 is a partially enlarged schematic diagram of a first peripheral region according to some embodiments of the present disclosure, and FIG. 16 is a cross-sectional view along a line DD′ in FIG. 15.

In some embodiments of the present disclosure, as shown in combination with FIG. 2, FIG. 15 and FIG. 16, the peripheral region NA includes a first peripheral region NA1 located on a side of the device region AA. The first peripheral region NA1 includes a power supply line transfer region DA and a pad region DB. The pad region DB is located on a side of the power supply line transfer region DA facing away from the device region AA. The pad region DB is electrically connected to a circuit board (not shown in the drawings), and the circuit board may be used to transmit display signals. The first peripheral region NA1 may be the “lower” border of the display panel 01.

The pad region DB may transmit the power signals transmitted by the circuit board to the power supply line transfer region DA. The power supply line transfer region DA may be used to transmit the received power signals to the first power supply line PVDD and the second power supply line PVEE.

In some embodiments of the present disclosure, the groove 31 is located between the power supply line transfer region DA and the pad region DB.

In some embodiments of the present disclosure, as shown in FIG. 16, in the direction Z perpendicular to the plane of the display panel 01, the encapsulation layer 40 covers the groove 31.

Through research, it has been found that there are usually fewer connection wiring between the power supply line transfer region DA and the pad region DB, and the encapsulation layer 40 can extend from the device region AA to the area between the power supply line transfer region DA and the pad region DB. Therefore, in some embodiments of the present disclosure, by providing the groove 31 between the power supply line transfer region DA and the pad region DB, while ensuring that the encapsulation layer 40 can fill at least part of the groove 31, it is beneficial to reduce the number of line changes of the connection wiring between the power supply line transfer region DA and the pad region DB, thereby reducing the manufacturing cost of the display panel 01.

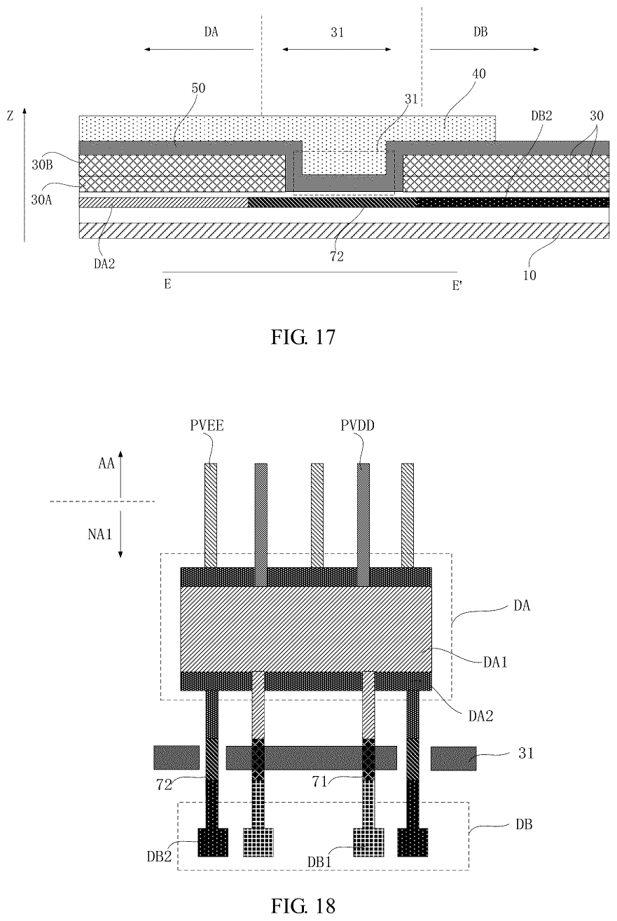

FIG. 17 is a cross-sectional view along a line EE′ in FIG. 15.

In some embodiments of the present disclosure, as shown in combination with FIG. 15, FIG. 16 and FIG. 17, the power supply line transfer region DA includes a first transfer electrode DA1 and a second transfer electrode DA2, and the pad region DB includes a first terminal DB1 and a second terminal DB2. There are a first connection line 71 and a second connection line 72 between the power supply line transfer region DA and the pad region DB. One end of the first connection line 71 is electrically connected to the first transfer electrode DA1, and the other end of the first connection line 71 is electrically connected to the first terminal DB1. One end of the second connection line 72 is electrically connected to the second transfer electrode DA2, and the other end of the second connection line 72 is electrically connected to the second terminal DB2.

The first terminal DB1 may receive the first power signals transmitted by the circuit board. The first connection line 71 may transmit the first power signals received by the first terminal DB1 to the first transfer electrode DA1. The first transfer electrode DA1 may transmit the received first power signals to the first power supply line PVDD. The second terminal DB2 may receive the second power signals transmitted by the circuit board. The second connection line 72 may transmit the second power signals received by the second terminal DB2 to the second transfer electrode DA2. The second transfer electrode DA2 may transmit the received second power signals to the second power supply line PVEE.

In some embodiments of the present disclosure, in the direction Z perpendicular to the plane of the display panel 01, at least one of the first connection line 71 and the second connection line 72 overlaps the groove 31.

In some embodiments of the present disclosure, as shown in combination with FIG. 15, FIG. 16 and FIG. 17, in the direction Z perpendicular to the plane of the display panel 01, both the first connection line 71 and the second connection line 72 overlap the groove 31. Based on this arrangement, it is beneficial to make the groove 31 a continuous structure, which is conducive to realizing the all-round blocking of the path through which the organic planarization layer 30 transmits water vapor to the interior of the display panel 01.

In some embodiments of the present disclosure, as shown in combination with FIG. 16 and FIG. 17, both the first connection line 71 and the second connection line 72 are located on a side of the first sub-layer 30A adjacent to the substrate 10. Based on this arrangement, the first connection line 71 and the second connection line 72 can be prepared on a same layer as other wiring on the side of the first sub-layer 30A adjacent to the substrate 10 without adding additional processes, thereby simplifying the manufacturing process of the display panel 01.

In some embodiments of the present disclosure, as shown in combination with FIG. 16 and FIG. 17, the first connection line 71 and the second connection line 72 are provided on a same layer, thereby further simplifying the structural complexity of the display panel 01 and reducing the design difficulty of the display panel 01.

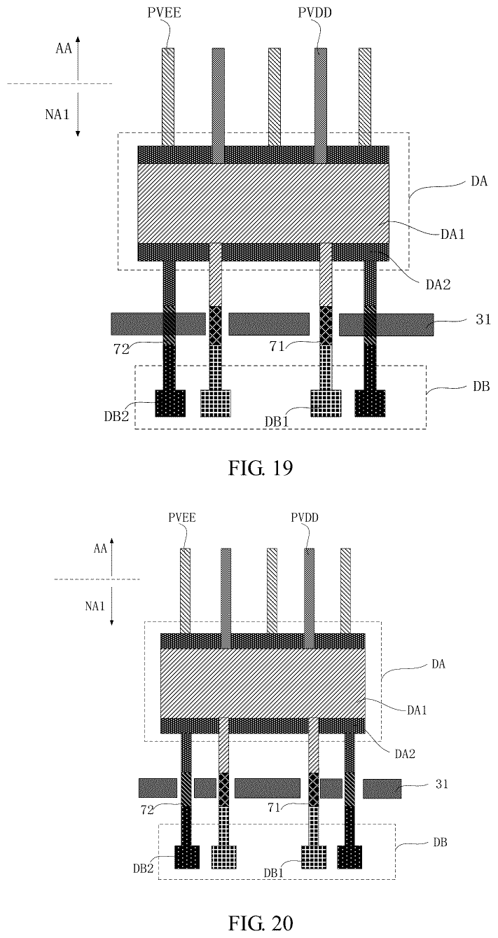

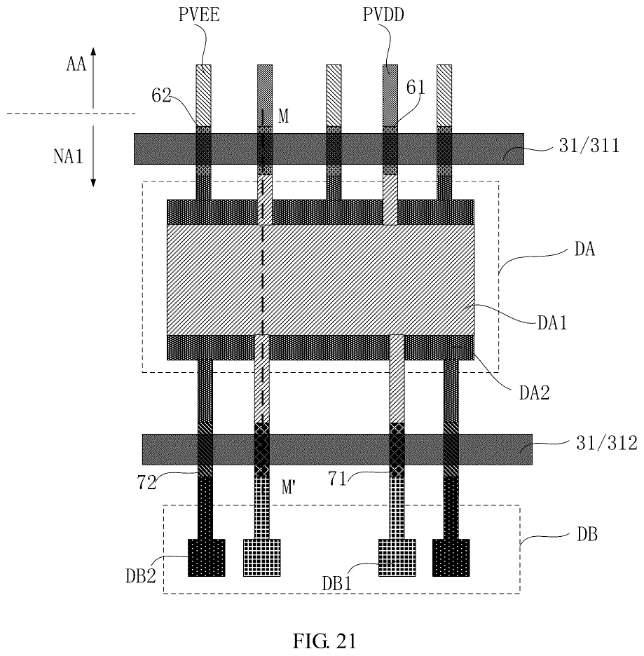

In some embodiments of the present disclosure, as shown in FIG. 18, which is a partially enlarged schematic diagram of a first peripheral region according to some embodiments of the present disclosure, in the direction perpendicular to the plane of the display panel 01, the first connection line 71 overlaps the groove 31, and the second connection line 72 does not overlap the groove 31. Based on this arrangement, the groove 31 can be a discontinuous structure that does not overlap the second connection line 72. While ensuring that the path through which the organic planarization layer 30 transmits water vapor to the interior of the display panel 01 can be blocked to a large extent, the connection between the second connection line 72 and the second transfer electrode DA2 does not require punching and layer changing, thereby simplifying the manufacturing process of the display panel 01 and reducing the manufacturing cost.

As shown in FIG. 19, which is a partially enlarged schematic diagram of a first peripheral region according to some embodiments of the present disclosure, in the direction perpendicular to the plane of the display panel 01, it may also be provided that the first connection line 71 does not overlap the groove 31, and the second connection line 72 overlaps the groove 31.

In some embodiments of the present disclosure, the first connection line 71 and the first transfer electrode DA1 are provided on a same layer, or the second connection line 72 and the second transfer electrode DA2 are provided on a same layer.

For example, as shown in combination with FIG. 16 and FIG. 17, the second connection line 72 and the second transfer electrode DA2 are provided on a same layer, and the first connection line 71 and the first transfer electrode DA1 are provided on different layers.

Based on this arrangement, there is no need to achieve electrical connection between the first connection line 71 and the first transfer electrode DA1 through punching, or there is no need to achieve electrical connection between the second connection line 72 and the second transfer electrode DA2 through punching, thereby simplifying the manufacturing process of the display panel 01 and saving costs.

FIG. 20 is a partially enlarged schematic diagram of a first peripheral region according to some embodiments of the present disclosure.

In some embodiments of the present disclosure, as shown in FIG. 20, the power supply line transfer region DA includes a first transfer electrode DA1 and a second transfer electrode DA2, and the pad region DB includes a first terminal DB1 and a second terminal DB2. There are a first connection line 71 and a second connection line 72 between the power supply line transfer region DA and the pad region DB. One end of the first connection line 71 is electrically connected to the first transfer electrode DA1, and the other end of the first connection line 71 is electrically connected to the first terminal DB1. One end of the second connection line 72 is electrically connected to the second transfer electrode DA2, and the other end of the second connection line 72 is electrically connected to the second terminal DB2.

In the direction perpendicular to the plane of the display panel 01, at least one of the first connection line 71 and the second connection line 72 does not overlap the groove 31.

In some embodiments of the present disclosure, as shown in FIG. 20, in the direction perpendicular to the plane where the display panel 01, neither the first connection line 71 nor the second connection line 72 overlaps the groove 31.

In some embodiments of the present disclosure, the groove 31 may be a discontinuous structure. While ensuring that the path through which the organic planarization layer 30 transmits water vapor to the interior of the display panel 01 can be blocked to a large extent, at least one of the first connection line 71 and the second connection line 72 does not need to be provided across the groove 31, thereby simplifying the manufacturing process of the display panel 01 and reducing the manufacturing cost.

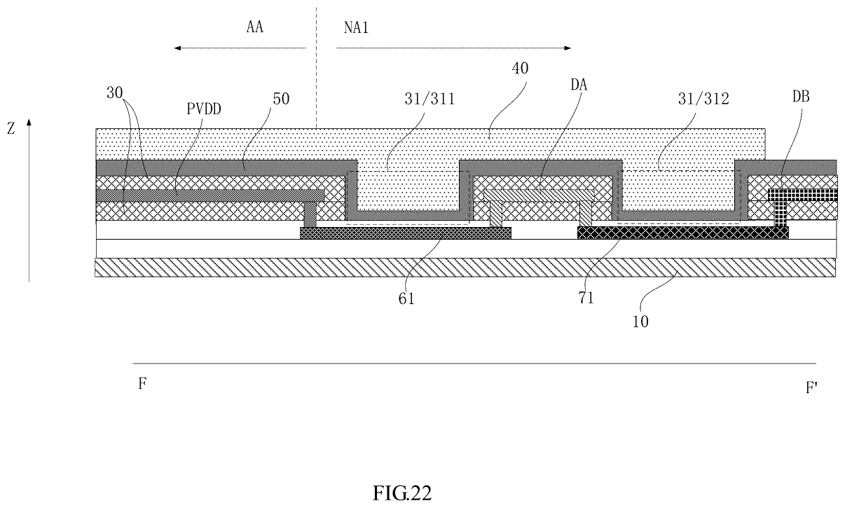

FIG. 21 is a partially enlarged schematic diagram of a first peripheral region according to some embodiments of the present disclosure, and FIG. 22 is a cross-sectional view along a line FF′ in FIG. 21.

In some embodiments of the present disclosure, as shown in combination with FIG. 21 and FIG. 22, the peripheral region NA includes a first peripheral region NA1 located on a side of the device region AA. The first peripheral region NA1 includes a power supply line transfer region DA and a pad region DB. The pad region DB is located on a side of the power supply line transfer region DA facing away from the device region AA. The pad region DB is electrically connected to a circuit board (not shown in the drawings), and the circuit board may be used to transmit display signals. The first peripheral region NA1 may be the “lower” border of the display panel 01.

The pad region DB may transmit the power signals transmitted by the circuit board to the power supply line transfer region DA. The power supply line transfer region DA may be used to transmit the received power signals to the first power supply line PVDD and the second power supply line PVEE.

The groove 31 includes a first groove 311 and a second groove 312. The first groove 311 is located between the power supply line transfer region DA and the device region AA, and the second groove 312 is located between the power supply line transfer region DA and the pad region DB.

In some embodiments of the present disclosure, the first groove 311 and the second groove 312 are provided in the first peripheral region NA1, and the first groove 311 and the second groove 312 are arranged along the direction from the device region AA to the edge of the display panel 01, so that the reliability of the groove 31 in blocking the water vapor transmission path of the organic planarization layer 30 is improved, thereby further preventing water vapor from intruding the interior of the display panel 01 along the organic planarization layer 30, and not damaging the components inside the display panel 01.

In some embodiments of the present disclosure, as shown in FIG. 21, both the first groove 311 and the second groove 312 are continuous structures. In this way, it is beneficial for both the first groove 311 and the second groove 312 to block the path through which the organic planarization layer 30 transmits water vapor to the interior of the display panel 01 in all directions, improving the reliability of blocking the water vapor transmission path of the organic planarization layer 30 to the interior of the display panel 01.

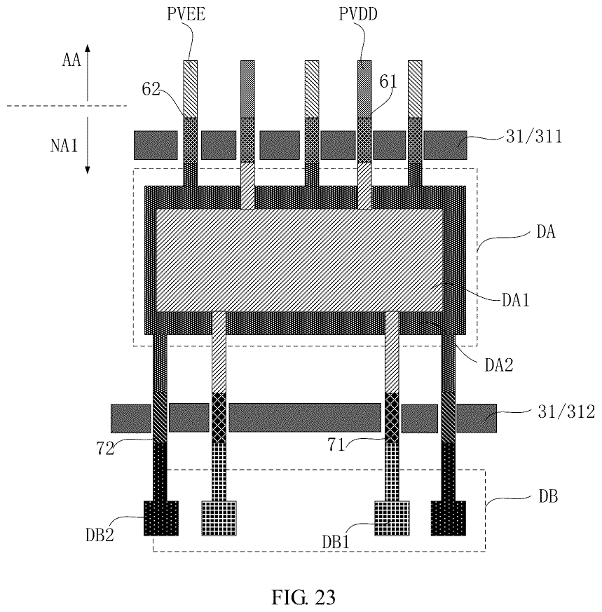

In some embodiments of the present disclosure, at least one of the first groove 311 and the second groove 312 is a discontinuous structure. In some embodiments of the present disclosure, as shown in FIG. 23, which is a partially enlarged schematic diagram of a first peripheral region according to some embodiments of the present disclosure, both the first groove 311 and the second groove 312 are discontinuous structures.

Based on this arrangement, in the direction Z perpendicular to the plane of the display panel 01, it is beneficial for at least one of the first groove 311 and the second groove 312 to have no overlap with the wiring in the display panel 01, thereby reducing the preparation of wiring crossing the first groove 311 or the second groove 312, and further reducing the preparation difficulty of the display panel 01 and saving costs.

In some embodiments of the present disclosure, along the arrangement direction of the first groove 311 and the second groove 312, projections of the second groove 312 and the first groove 311 on the same plane form a continuous structure. In this way, it is beneficial for the first groove 311 and the second groove 312 to complement and cooperate with each other to achieve the all-round blocking of the path through which the water vapor is transmitted to the interior of the display panel 01 along the organic planarization layer 30.

In some embodiments of the present disclosure, as shown in FIG. 23, in the first peripheral region NA1, both the first groove 311 and the second groove 312 are discontinuous structures. In the directions where the second groove 312 cannot block the water vapor transmission of the organic planarization layer 30, the first groove 311 can block it. In the directions where the first groove 311 cannot block the water vapor transmission of the organic planarization layer 30, the second groove 312 can block it. While achieving the all-round blocking of the water vapor transmission path along the organic planarization layer 30, it is beneficial for reducing the preparation of wiring crossing the first groove 311 or the second groove 312, and reducing the preparation difficulty of the display panel 01.

In some embodiments of the present disclosure, in the first peripheral region NA1, at least one of the first groove 311 and the second groove 312 may also be a continuous structure. While achieving the all-round blocking of the water vapor transmission path along the organic planarization layer 30, in at least some directions, the first groove 311 and the second groove 312 can achieve double blocking of the water vapor transmission path of the organic planarization layer 30, thereby improving the reliability of blocking the water vapor transmission path along the organic planarization layer 30.

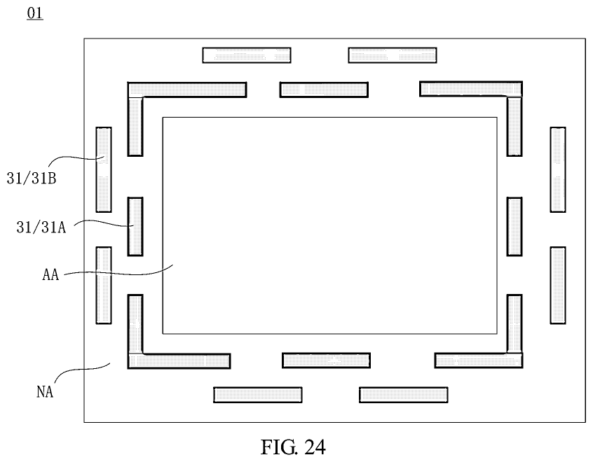

FIG. 24 is a planar schematic diagram of a display panel according to some embodiments of the present disclosure.

In some embodiments of the present disclosure, as shown in FIG. 24, in the peripheral region NA, at least two grooves 31 are provided in the organic planarization layer. The at least two grooves 31 are arranged along the direction from the device region AA to the peripheral region NA. That is, along the direction from the device region AA to the edge of the display panel 01, the at least two grooves 31 can successively block the path through which external water vapor is transmitted to the interior of the display panel 01 along the organic planarization layer 30.

Along the direction from the device region AA to the peripheral region NA, the projections of the at least two grooves 31 on the same plane form a continuous structure.

In some embodiments of the present disclosure, as shown in FIG. 24, the at least two grooves 31 include a groove 31A and a groove 31B. The projection of the groove 31B on the plane where the groove 31A is located forms a continuous structure with the groove 31A. The groove 31A and the groove 31B may both be continuous structures, both be discontinuous structures, or one may be a continuous structure and the other be a discontinuous structure. FIG. 24 only shows the case where both the groove 31A and the groove 31B are discontinuous structures.

In some embodiments of the present disclosure, the at least two grooves 31 can complement and cooperate with each other to achieve the all-round blocking of the path through which the water vapor is transmitted to the interior of the display panel 01 along the organic planarization layer 30. Moreover, providing at least two grooves 31 in the embodiments of the present disclosure is also beneficial for increasing the structural diversity of the display panel 01.

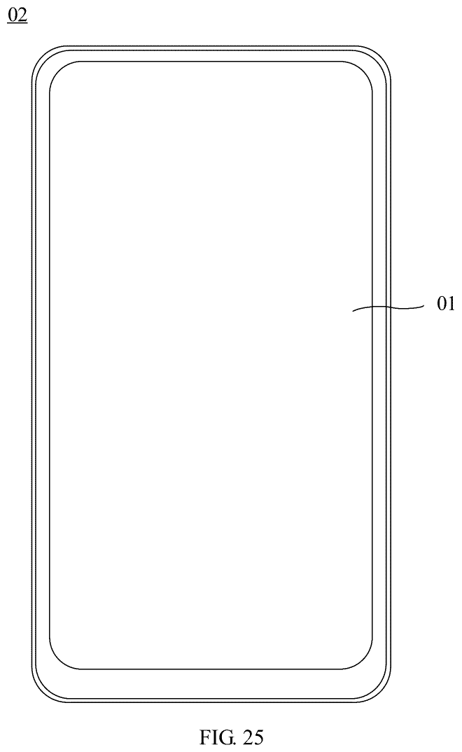

FIG. 25 is a schematic diagram of a display apparatus according to some embodiments of the present disclosure.

Embodiments of the present disclosure provide a display apparatus 02. As shown in FIG. 25, the display apparatus 02 includes the display panel 01 provided in the above embodiments. In some embodiments of the present disclosure, the display apparatus 02 may be an electronic device such as a mobile phone, a computer, a TV, a wearable display, or a vehicle-mounted display. The present disclosure does not make specific limitations.

In the display apparatus 02, by providing a groove 31 in the organic planarization layer 30, the solid portion of the organic planarization layer 30 can be disconnected or terminated at the groove 31. If the solid portion of the organic planarization layer 30 is disconnected at the groove 31 and the encapsulation layer 40 fills at least part of the groove 31, the encapsulation layer 40 can be located between the disconnected solid portions of the organic planarization layer 30, so that the path through which the organic planarization layer 30 transmits external water vapor is blocked, thereby preventing external water vapor from intruding the interior of the display panel 01 through the organic planarization layer 30, and not damaging the components inside the display panel 01.

If the solid portion of the organic planarization layer 30 is terminated at the groove 31 and the encapsulation layer 40 fills at least part of the groove 31, the encapsulation layer 40 can relatively reliably cover the sidewall of the solid portion of the organic planarization layer 30 facing towards the edge of the display panel 01, so that external water and oxygen are prevented from intruding the organic planarization layer 30, thereby preventing external water vapor from intruding the interior of the display panel 01 along the organic planarization layer 30, and not damaging the components inside the display panel 01.

The above are only the preferred embodiments of the present disclosure and are not intended to limit the present disclosure. Any modifications, equivalent replacements, improvements, etc. made within the spirit and principles of the present disclosure shall be included in the protection scope of the present disclosure.

What is claimed is:

1. A display panel, comprising:
a device region;
a peripheral region located on a side of the device region facing towards an edge of the display panel;
a substrate;
a transistor array layer;
an organic planarization layer; and
an encapsulation layer,
wherein the organic planarization layer is located on a side of the transistor array layer facing away from the substrate, and the encapsulation layer is located on a side of the organic planarization layer facing away from the substrate;
wherein the organic planarization layer and the encapsulation layer extend from the device region to the peripheral region; and
wherein in the peripheral region, the organic planarization layer is provided with a groove, and the encapsulation layer fills at least part of the groove.

2. The display panel according to claim 1, wherein the encapsulation layer is a water-blocking layer, or
wherein the display panel further comprises a first inorganic layer extending from the device region to the peripheral region, wherein the first inorganic layer is located between the encapsulation layer and the organic planarization layer, and in the peripheral region, the first inorganic layer is adhered to a surface of the organic planarization layer.

3. The display panel according to claim 1, wherein in the peripheral region, the organic planarization layer comprises a first sub-portion and a second sub-portion, and the groove is located between the first sub-portion and the second sub-portion.

4. The display panel according to claim 3, wherein the second sub-portion is located on a side of the first sub-portion facing towards the edge of the display panel, the first sub-portion comprises a first side surface facing towards the second sub-portion, and the second sub-portion comprises a second side surface facing towards the first sub-portion, and
wherein in a direction perpendicular to a plane of the display panel, the encapsulation layer covers the first side surface and the second side surface.

5. The display panel according to claim 1, wherein in the peripheral region, the organic planarization layer comprises a solid portion, the groove is located on a side of the solid portion facing towards the edge of the display panel, and the solid portion comprises a third side surface facing towards the edge of the display panel, and
wherein in the direction perpendicular to the plane of the display panel, the encapsulation layer covers the third side surface.

6. The display panel according to claim 1, further comprising a first power supply line and a second power supply line, wherein the organic planarization layer comprises a first sub-layer and a second sub-layer, the first sub-layer is located on a side of the second sub-layer adjacent to the substrate, the first power supply line is located between the first sub-layer and the second sub-layer, and the second power supply line is located on a side of the second sub-layer facing away from the first sub-layer.

7. The display panel according to claim 6, wherein the peripheral region comprises a first peripheral region located on one side of the device region, and the first peripheral region is electrically connected to a circuit board; and
wherein the first peripheral region comprises a power supply line transfer region, and the groove is located between the power supply line transfer region and the device region.

8. The display panel according to claim 7, wherein the first peripheral region comprises a first transfer line and a second transfer line, the first transfer line is electrically connected to the first power supply line, and the second transfer line is electrically connected to the second power supply line, the first transfer line and the second transfer line extend to the power supply line transfer region; and
wherein in the direction perpendicular to a plane of the display panel, at least one of the first transfer line and the second transfer line overlaps the groove.

9. The display panel according to claim 8, wherein in the direction perpendicular to the plane of the display panel, the first transfer line and the second transfer line both overlap the groove.

10. The display panel according to claim 9, wherein the first transfer line and the second transfer line are provided on a same layer; or
wherein the first transfer line and the second transfer line are located on a side of the first sub-layer adjacent to the substrate.

11. The display panel according to claim 9, wherein the power supply line transfer region comprises a first transfer electrode and a second transfer electrode, one end of the first transfer line is electrically connected to the first power supply line, and the other end of the first transfer line is electrically connected to the first transfer electrode, one end of the second transfer line is electrically connected to the second power supply line, and the other end of the second transfer line is electrically connected to the second transfer electrode.

12. The display panel according to claim 11, wherein the first transfer line is electrically connected to the first transfer electrode at least through a first via hole, and the second transfer line is electrically connected to the second transfer electrode at least through a second via hole; or
wherein the first transfer line and the first transfer electrode are provided on a same layer, or the second transfer line and the second transfer electrode are provided on a same layer.

13. The display panel according to claim 7, wherein the first power supply line and the second power supply line extend to the power supply line transfer region; and
wherein in the direction perpendicular to the plane of the display panel, at least one of the first power supply line and the second power supply line does not overlap the groove.

14. The display panel according to claim 7, wherein the first peripheral region comprises a light-shielding layer, the light-shielding layer is located on a side of the encapsulation layer facing away from the substrate; and
wherein in the direction perpendicular to the plane of the display panel, the light-shielding layer overlaps the groove.

15. The display panel according to claim 7, wherein the first peripheral region comprises a first inorganic layer and a light-shielding layer, the first inorganic layer adheres to a surface of the organic planarization layer, and the light-shielding layer is located between the encapsulation layer and the first inorganic layer; and
wherein in the direction perpendicular to the plane of the display panel, the light-shielding layer overlaps the groove.

16. The display panel according to claim 6, wherein the peripheral region comprises a first peripheral region, the first peripheral region comprises a power supply line transfer region and a pad region, the pad region is located on a side of the power supply line transfer region facing away from the device region, and the pad region is electrically connected to a circuit board; and wherein the groove is located between the power supply line transfer region and the pad region; or
wherein the power supply line transfer region comprises a first transfer electrode and a second transfer electrode, the pad region comprises a first terminal and a second terminal, a first connection line and a second connection line are provided between the power supply line transfer region and the pad region, one end of the first connection line is electrically connected to the first transfer electrode, and the other end of the first connection line is electrically connected to the first terminal, one end of the second connection line is electrically connected to the second transfer electrode, and the other end of the second connection line is electrically connected to the second terminal; and wherein in the direction perpendicular to the plane of the display panel, at least one of the first connection line and the second connection line does not overlap the groove.

17. The display panel according to claim 16, wherein the power supply line transfer region comprises a first transfer electrode and a second transfer electrode, the pad region comprises a first terminal and a second terminal, a first connection line and a second connection line are provided between the power supply line transfer region and the pad region, one end of the first connection line is electrically connected to the first transfer electrode, and the other end of the first connection line is electrically connected to the first terminal, one end of the second connection line is electrically connected to the second transfer electrode, and the other end of the second connection line is electrically connected to the second terminal; and
wherein in the direction perpendicular to the plane of the display panel, at least one of the first connection line and the second connection line overlaps the groove.

18. The display panel according to claim 1, wherein the peripheral region comprises a first peripheral region located on a side of the device region, the first peripheral region comprises a power supply line transfer region and a pad region, the pad region is located on a side of the power supply line transfer region facing away from the device region, and the pad region is electrically connected to a circuit board; and
wherein the groove comprises a first groove and a second groove, the first groove is located between the power supply line transfer region and the device region, and the second groove is located between the power supply line transfer region and the pad region.

19. The display panel according to claim 18, wherein along an arrangement direction of the first groove and the second groove, projections of the second groove and the first groove on a same plane form a continuous structure.

20. A display apparatus, comprising a display panel, wherein the display panel comprises:
a device region;
a peripheral region located on a side of the device region facing towards an edge of the display panel;
a substrate;
a transistor array layer;
an organic planarization layer; and
an encapsulation layer,
wherein the organic planarization layer is located on a side of the transistor array layer facing away from the substrate, and the encapsulation layer is located on a side of the organic planarization layer facing away from the substrate;
wherein the organic planarization layer and the encapsulation layer extend from the device region to the peripheral region; and
wherein in the peripheral region, the organic planarization layer is provided with a groove, and the encapsulation layer fills at least part of the groove.
